(19) United States
(12) Patent Application Publication
(10) Pub. No.: US 2008/0062767 A1
(43) Pub. Date: Mar. 13, 2008

(54) METHOD OF FIXING A READ EVALUATION TIME OR THE DIFFERENCE BETWEEN A READ CHARGE VOLTAGE AND A READ DISCRIMINATING VOLTAGE IN A NON-VOLATILE NAND TYPE MEMORY DEVICE

(75) Inventors: Luca CRIPPA, Busnago (IT); Roberto RAVASIO, Presezzo (IT); Rino MICHELONI, Turate (IT)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignees: STMicroelectronics S.r.l., Agrate Brianza (MI) (IT); Hynix Semiconductor Inc., Ichon-si (KR)

(21) Appl. No.: 11/854,713

(22) Filed: Sep. 13, 2007

(30) Foreign Application Priority Data
Sep. 13, 2006 (EP) 06425631.6

(51) Int. Cl. G11C 16/04

(52) U.S. Cl. 365/185.18; 365/185.21

(57) ABSTRACT

The evaluation time or the difference between the read charge voltage and the read discrimination voltage of the programmed or erased state of a cell of a NAND memory array is set for the individual memory device. This is done in such a way that at least partially compensates the generally large spread of parasitic capacitance values of the array bitlines in the mass production fabrication process of the NAND memory array.

### FIELD OF THE INVENTION

The present invention relates generally to non-volatile memory devices and, more particularly, to NAND-type devices.

### BACKGROUND OF THE INVENTION

The evaluation time of the programmed or erased state of a cell of a non-volatile NAND memory array during read or verify operations is normally fixed during a test-on-wafer phase of the devices. Alternatively, this may be set by a board microcontroller at a power on of the device by executing a self-configuration program code stored with pre-established configuration values.

A typical circuit diagram for read (evaluation) operations of NAND memory devices is depicted in FIG. 1. The scheme contemplates the charging to a certain read voltage V1 of the capacitance associated to a bitline BL. Referring to the diagram of FIG. 1 and to the relative timing diagram of FIG. 2, at the instant T1 the switch SW1 opens, which leaves the bitline BL charged at the read voltage V1. Simultaneously, the NAND string to which the selected cell belongs is activated through a row decoding circuit, electrically represented by the switch SW2 and the relative current generator Icell of FIG. 1.

Assuming that the current flowing through the cell string is constant and depends solely from the threshold voltage of the selected cell and from the voltage of the selected wordline WL, the current generator Icell starts to discharge the bitline BL at the instant T1.

Accordingly the voltage on the bitline BL evolves according to the following equation:

V_{BL}(t)=V1−Icell*Teval/C_{BL} (1)

The evaluation time interval is given by:

Teval=T2−T1 (2)

At the end of the evaluation time internal Teval (instant T2), the result of the comparison between the voltage on the bitline BL and the discrimination voltage threshold V2 determines the value that is recognized by the discriminating circuit DEC, according to the following criteria:

| | |
|---|---|
| if VBL(T2) > V2 | |
| Cell @ 0 | |
| else | |
| Cell @ 1 | (3) |
| end if. | |

When a cell threshold voltage is incremented, such as for a predetermined voltage (PV) applied to the relative wordline WL, the current flowing through the cell at the end of the evaluation time will have decreased to a value such that:

VBL(T2)≧V2 (4)

and, therefore the cell will be recognized as having a logic 0 content, as depicted in FIG. 3. At equilibrium, the following equation holds:

V₂=V₁−Icell*Teval/C_{BL} (5)

Once the voltage levels V1 and V2 and the evaluation time interval Teval are fixed, the maximum value of current flowing through the cell for which the cell is recognized as being programmed to the logic value 0 will be determined by the capacitance of the relative bitline BL:

Icell=(V₁−V₂)*C_{BL}/Teval (6)

Should the capacitance of all the bitlines of the memory array be equal, all the cells would have the same discharge current. Unfortunately, this is not the case because the capacitance of the bitlines as normally set out in a design rule manual of these memory devices is extremely variable. The design rule is normally indicated with a ±50% range of variability, as graphically depicted in FIG. 4. As a consequence, the value of the current flowing through a cell, given by the relationship (6), has a large variance.

In FIG. 8 are depicted the currents through a cell during the charging phase (time interval 0-T1), and during the discharge phase (time interval T1-T2) for three different bitlines BL. The currents respectively have a minimum capacitance (Cmin), a typical capacitance (Ctyp) and a maximum capacitance (Cmax) of an indicated range of variability associated therewith.

FIG. 6 represents the electrical charges Q_{Cmax} Q_{Cmin} and Q_{Ctyp} that are stored in the respective bitline. Thus, the turning point of a cell shifts considerably over its characteristic. Therefore, when designing the memory device, there is a need to provide for any possible value of capacitance of the single array bitline. There will be a working point (or turning point current) (Iturn<ICmax) that will have an adequate safety margin in order to avoid zones that are very non-linear of the characteristic curve (e.g., the bottom and top darker regions in the diagram of FIG. 7).

With the constant reduction of the sizes of integrated structures, the maximum current through the cells (Icell max) diminishes while the spread of parasitic capacitance values of the bitlines increases.

This makes it more difficult to define an operating zone that will function correctly.

Tests have revealed that the spread of bitline parasitic capacitance values commonly reported in a design rule manual of memory devices in order to enable the designer to establish with a sufficiently safe margin factor the operating point or zone of operation that will ensure a faultless functioning of the device compounds different spread contributions. These factors include an intra-die topological variability, an intra-lot of wafer spread as depicted in FIG. 8, and the spread among different lots of wafers as depicted in FIG. 9.

Recognition of the relative weights of the above-mentioned bitline parasitic capacitance values spread contributions to the compound spread values indicated in design rule manuals.

### SUMMARY OF THE INVENTION

In view of the foregoing background, an object of the invention is to provide an effective way of contrasting the shrinking of the secure operating zone of the electrical characteristics of scalded down cell arrays of a memory device by fixing or setting an appropriate evaluation time interval (Teval).

This and other objects, advantages and features in accordance with the invention are provided by a method of fixing or setting the appropriate evaluation time interval based on a specific parasitic capacitance value of the bitlines of the memory cell array assessed for each individual device either a during a one time a test-on-wafer phase or by repeatedly using the finished memory device.

The evaluation time (Teval) of the programmed or erased state of a cell of the NAND memory array may be set for the individual memory device in a way that at least partially compensates the generally large spread of parasitic capacitance values of the array bitlines in the mass production fabrication process of these devices.

Of course, the optimized establishing of working or operating parameters of the single device may even be implemented by adjusting the difference between the read charge voltage (V1) and the read discrimination voltage (V2), or alternatively the fixing or setting of the evaluation time (Teval) may compensate a process spread of such a voltage difference, as will be evident to those skilled in the art.

According to a preferred embodiment, an average value of capacitance of a single bitline of the memory array assessed for a certain lot of wafers may e used during the test-on-wafer phase for fixing the most appropriate evaluation time. This takes advantage of the significantly narrower intra-lot spread of bitline parasitic capacitance values compared to the compounded spread indicated in the design rule manual of the device.

A more preferred embodiment contemplates the integration of dedicated internal circuit structures for measuring the average parasitic capacitance of the bitlines of the memory cell array of the individual device.

According to yet another embodiment, one or more dummy bitlines and associated circuit structures may be formed for measuring the average time needed by the dummy bitlines to discharge from the read charge voltage V1 to the read discrimination voltage V2 with a desired current Icella. Given that it may be reasonably assumed that the dummy bitlines have the same capacitance of the user addressable bitlines, the evaluation time Teval may be fixed equal to the measured time interval.

### BRIEF DESCRIPTION OF THE DRAWINGS

Sample embodiments of the invention will be described referring to the attached drawings, wherein:

FIG. 1 depicts schematically a bitline of a non-volatile NAND memory device and the circuit used for discriminating the state of a cell according to the prior art;

FIG. 2 is a graph of the charge voltage of a bitline during a read operation according to the prior art;

FIG. 3 depicts four sample voltage-current characteristics of a memory cell according to the prior art;

FIG. 4 depicts a sample tolerance range of the mean value of the capacitance of a bitline as indicated in the Design Rule Manual according to the prior art;

FIG. 5 is a graph of the maximum, minimum and typical discharge currents of a bitline during a read operation according to the prior art;

FIG. 6 is a graph of the maximum, minimum and typical electrical charges stored in a bitline during a read operation according to the prior art;

FIG. 7 highlights the preferred functioning zone of the voltage-current characteristic of a bitline according to the invention;

FIG. 8 depicts a typical range of tolerance of the mean value of the capacitance of the bitlines of a memory device as measured during a test on wafer (EWS) phase;

FIG. 9 depicts a typical tolerance range of the mean value of the capacitance of the bitlines of all memory devices of a wafer as measured during a test on wafer (EWS) phase according to the invention;

FIG. 10 is a basic flow chart that shows how the EWS phase is modified according to a first embodiment of the invention;

FIG. 11 depicts the page buffers and the selection switches of the bitlines of a non-volatile NAND memory device according to the invention;

FIG. 12 illustrates the various coupling capacitances of a bitline with various parts of the memory device according to the invention;

FIG. 13 depicts a first embodiment of a non-volatile memory device according to the invention that includes a circuit for establishing an evaluation time for discriminating the state of a cell being read;

FIGS. 14 and 15 illustrate two functioning conditions of the device of FIG. 13;

FIG. 16 depicts timing graphs of the main signals of the memory device of FIGS. 14 and 15;

FIG. 17 depicts a second embodiment of a non-volatile memory device according to the invention that includes another circuit for establishing an evaluation time for discriminating the state of a cell being read;

FIG. 18 depicts timing graphs of the main signals of the memory device of FIG. 17;

FIG. 19 schematically illustrates a third embodiment of a non-volatile memory device according to the invention that includes at least a dummy bitline and a dummy page buffer specifically designed for establishing the evaluation time of the bitlines effectively made available to a user;

FIG. 20 schematically illustrates how a microprocessor integrated in the memory device of FIG. 19 measures the evaluation time of a dummy bitline, and uses this information for controlling the page buffers of the memory;

FIG. 21 is a detailed view of the dummy page buffer depicted in FIGS. 19 and 20;

FIG. 22 depicts timing graphs of the main signals of the memory device of FIGS. 20 and 21;

FIG. 23a is a graph of the bitline voltage of a bitline during a read operation wherein the read charge voltage V1 has been adjusted according to an alternative embodiment of the invention;

FIG. 23b is a graph of the bitline voltage of a bitline during a read operation wherein the read discriminating voltage V2 has been adjusted according to a further alternative embodiment of the method of the invention; and

FIG. 24 is a basic flow chart that shows how the EWS phase is modified according to another embodiment of the invention.

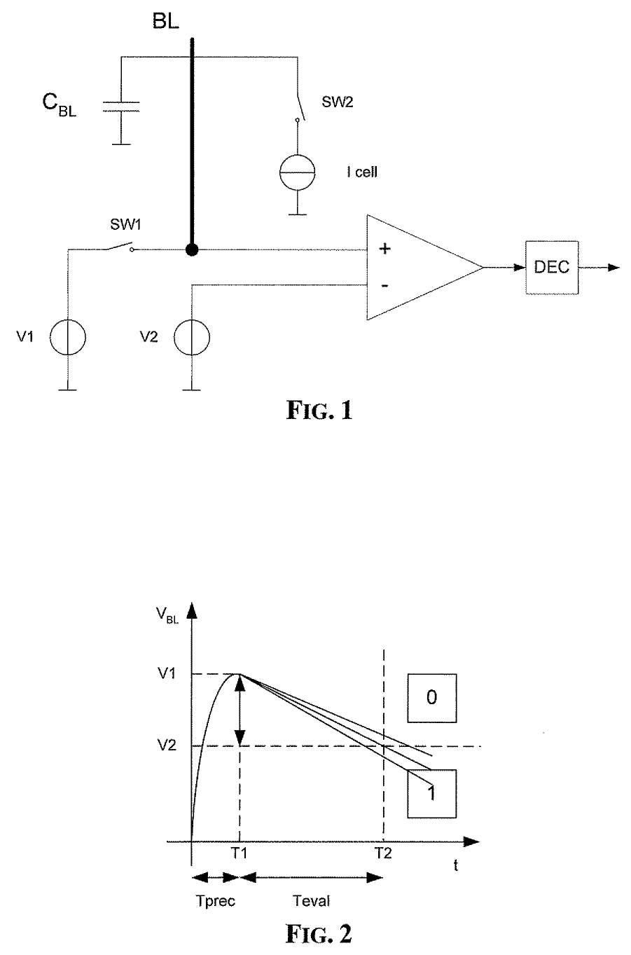

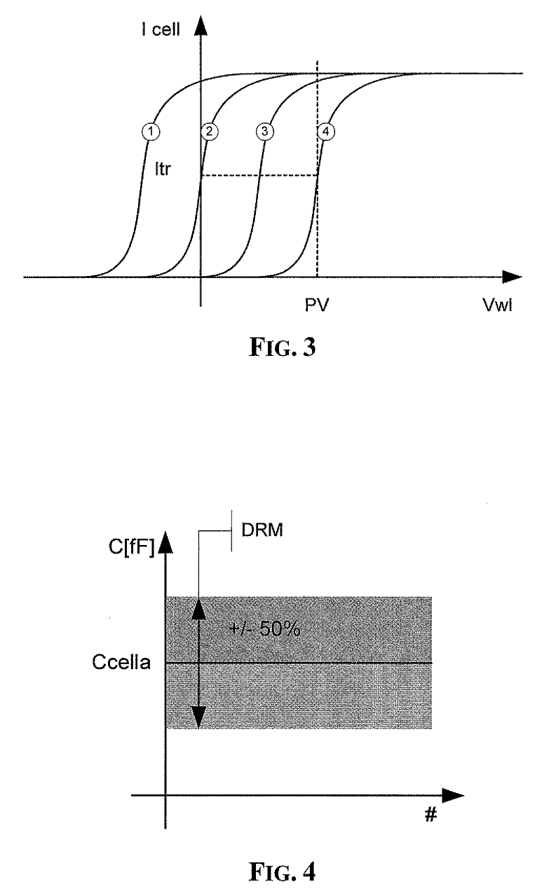

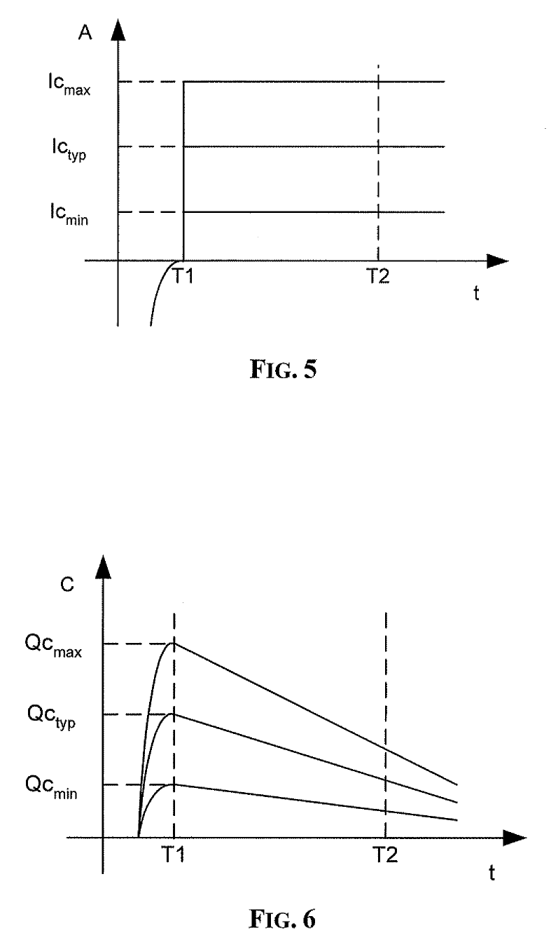

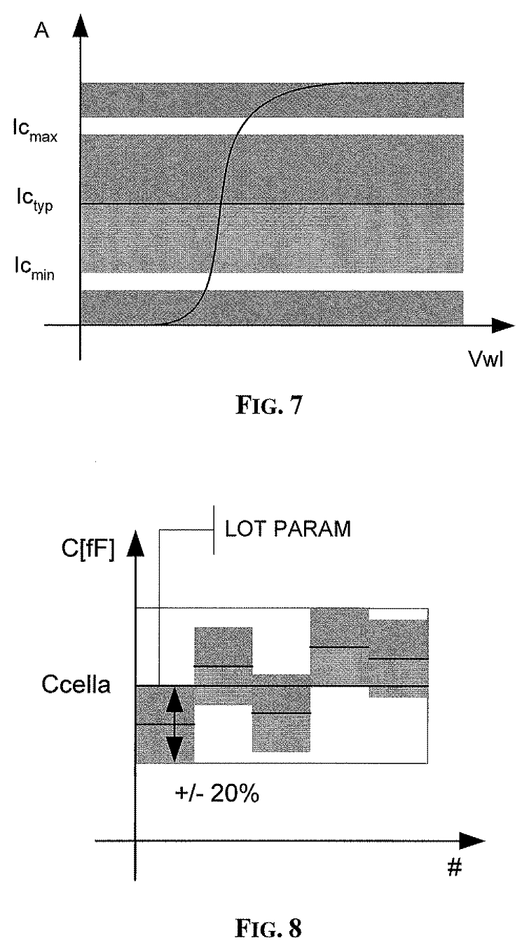

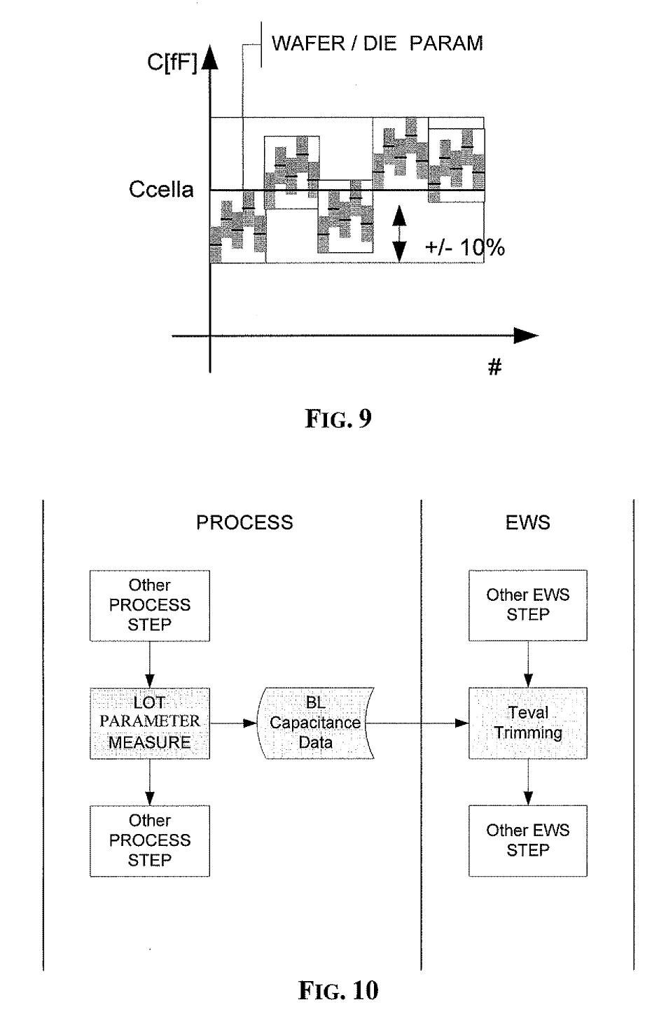

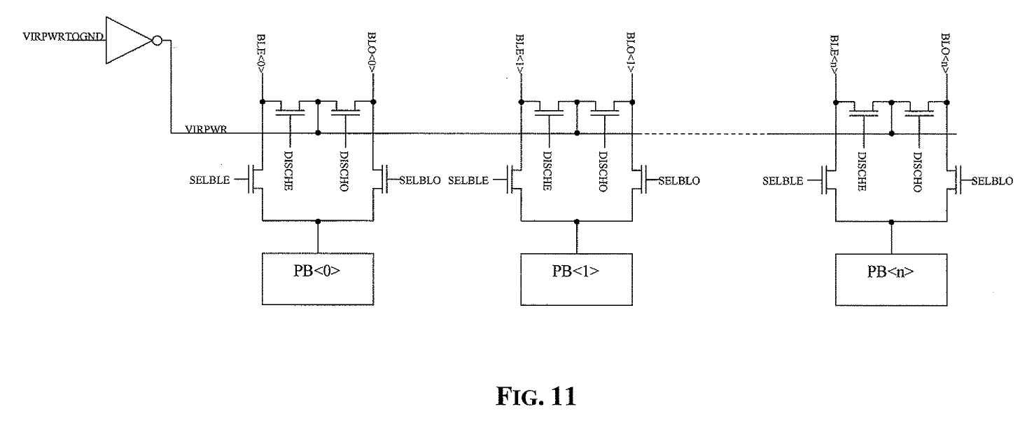

### DETAILED DESCRIPTION OF THE PREFERRED EMBODIMENTS

The invention provides methods for fixing or setting the evaluation time necessary for discriminating the state of a memory cell being read. It further provides a method of fixing or setting the difference between the read charge voltage V1 and the read discrimination voltage V2 with a trimming operation, such as a fuse trimming, during an EWS phase, having preliminarily fixed the evaluation time.

Hereinafter, reference will be made to memory cells that may assume one of two possible logic states, but the same considerations also hold for memory cells capable of storing more than one bit.

First and second methods contemplate the operation of determining the evaluation time by measuring during a test on wafer (EWS) phase the mean capacitance C_{BL} of the bitlines, and calculating as a function thereof the read charge voltage V1, the read discrimination voltage V2 and a certain pre-established discharge current Icell through the cell during a read operation.

According to the first and second methods, the evaluation time Teval may be fixed once and for all by trimming the non-volatile memory device during the EWS phase, or it may be fixed at each power on of the memory device, or when an erase phase or a read phase is started.

The mean capacitance C_{BL} of the bitlines may be determined during an EWS phase of the device being fabricated by measuring the capacitance of the bitlines of the memory device (FIG. 8), or of the bitlines of all the memory devices on a same wafer (FIG. 9). The capacitance measured in this phase is determined with a tolerance range that is relevantly smaller than that indicated in the Design Rule Manual (FIG. 4). This approach uses the calculated mean value that allows the evaluation time Teval to be determined in a more precise manner.

It is evident that carrying out such a modified EWS phase, as schematically sketched in FIG. 10, on a NAND memory device (FIG. 11) being fabricated would significantly improve the precision of the discrimination of the state of a cell being read. This reduces the error probability of a read operation.

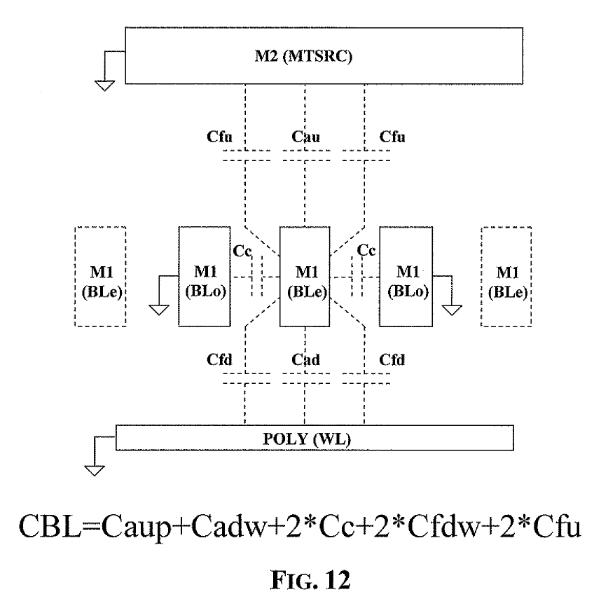

As an alternative, it is possible to measure the mean total capacitance value C_{BL} of a bitline (i.e., the sum of various contributions as shown in FIG. 12) with a dedicated circuit integrated with the memory device. The value C_{BL} may be used for fixing the evaluation time at the power on of the memory device, or when an erase or read operation is started.

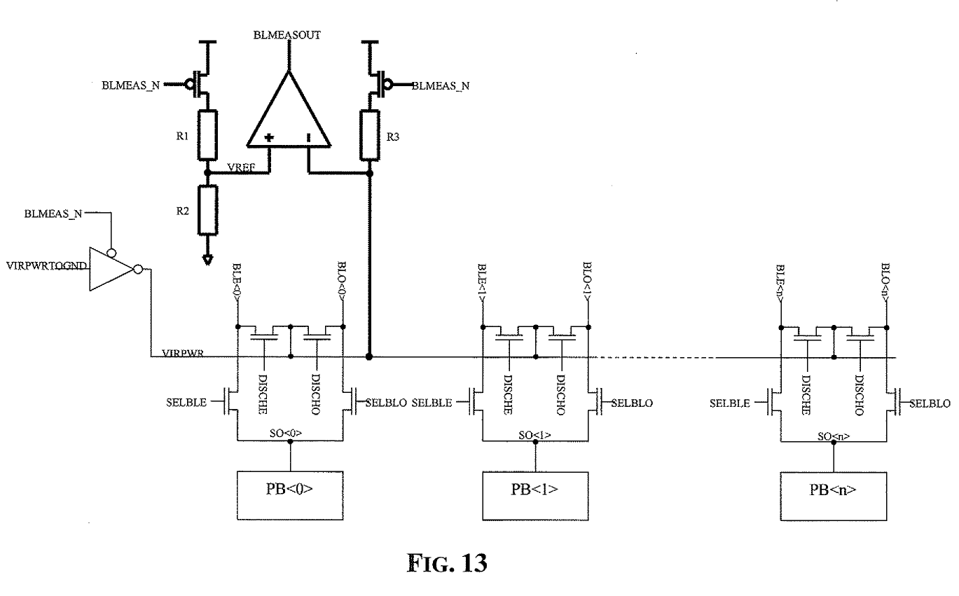

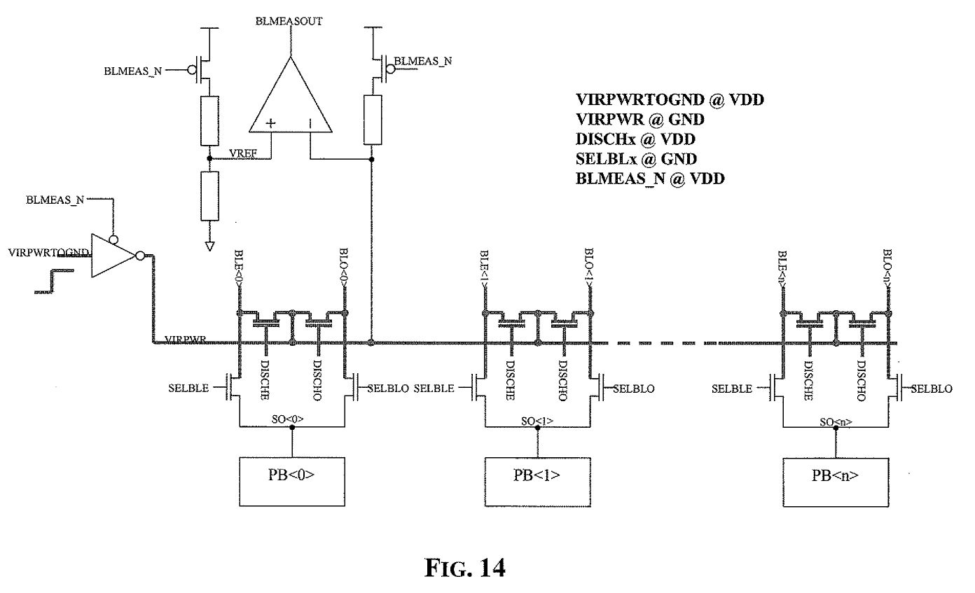

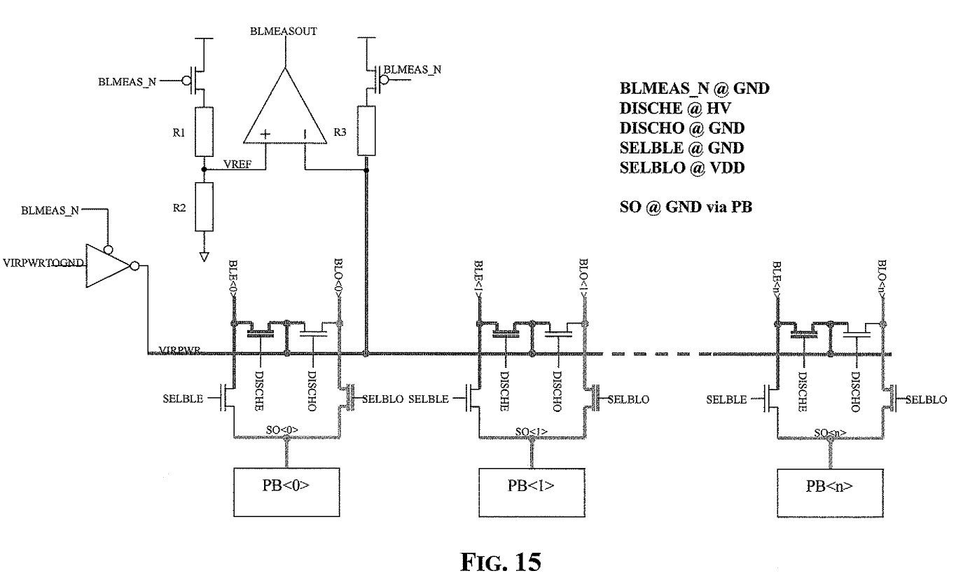

FIG. 13 depicts a memory device that integrates a dedicated circuit (drawn with a thick line) for measuring the mean capacitance C_{BL}. This dedicated circuit allows calculation of the total capacitance of a plurality of bitlines by connecting in parallel to a common line VIRPWR the plurality of bitlines. For example, the bitlines may be the even or the odd bitlines of the memory device. The mean capacitance C_{BL} is obtained by dividing the total capacitance by the number of bitlines connected in parallel.

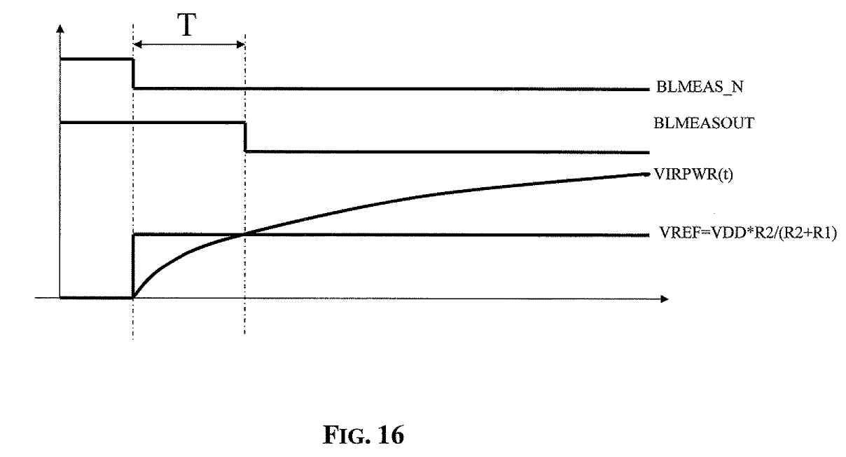

As will now be described in greater detail, the total capacitance is measured as follows. First, all the bitlines of the memory device are grounded by connecting them to the common line VIRPWR. This is done by enabling the signals DTSCHE and DISCHO (FIG. 14) when the line VIRPWR is at a ground potential (i.e., when the signal VIRPWRTOGND is active).

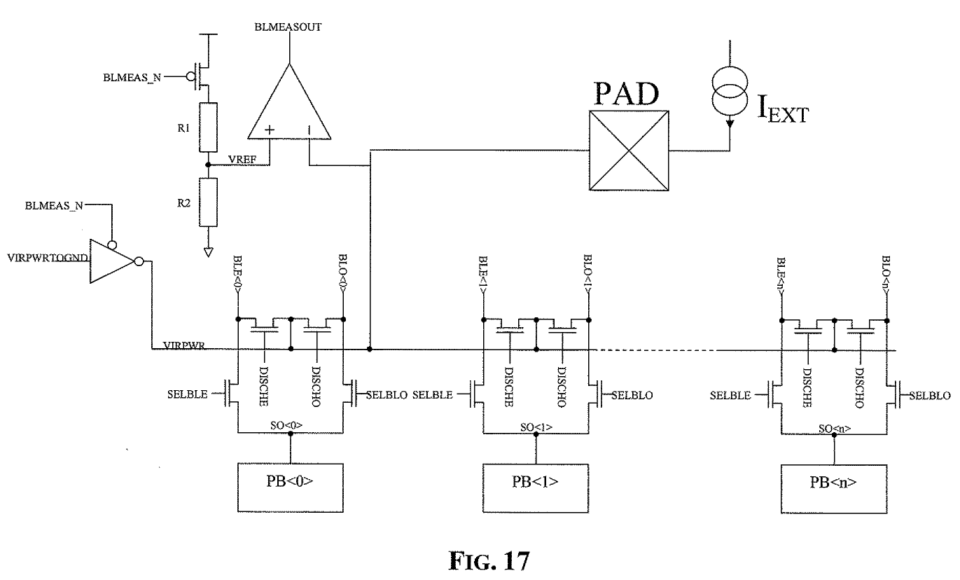

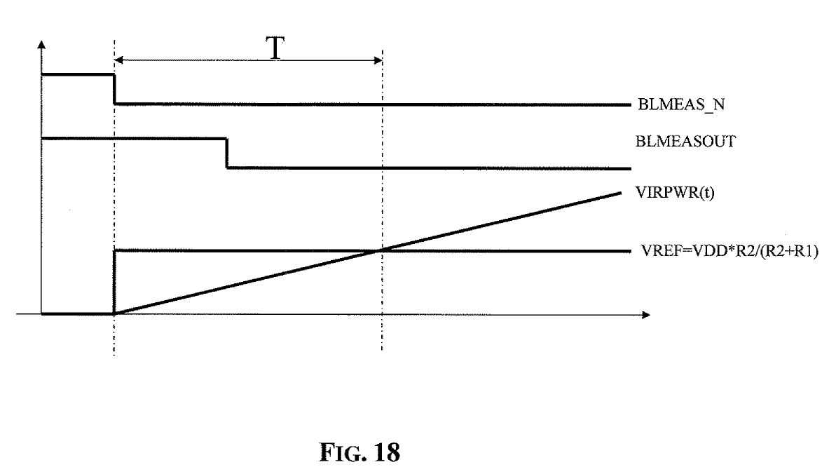

Then the odd or even bitlines are kept grounded (FIG. 15) by disabling the signal DISCHO or DISCHE and enabling the signals SELBLO or SELBLE, respectively. While the odd or even bitlines, respectively, are kept grounded, the signal BLMEAS_N is disabled (FIG. 16). As a result, the common line VIRPWR is left floating (tri-stated) and is charged through the resistor R3. When the voltage on the tri-stated common line VIRPWR reaches the reference voltage VREF generated by the voltage divider R1, R2, the flag BLMEASOUT switches.

By measuring the time T required for charging the common line VIRPWR, it is possible to calculate the total capacitance of the even or odd (or all) bitlines. Indeed,

$$V REF = V D D \cdot \frac{R 2}{R 1 + R 2} \qquad ( 1 )$$

and the voltage on the common line VIRPWR increases according to the following equation:

$$V I R PWR ( t ) = V D D \cdot ( 1 - exp ( - \frac{t}{R 3 \cdot n \cdot {C}_{BL}} ) ) \qquad ( 2 )$$

where n is the number of bitlines connected in parallel to the common line VIRPWR. Therefore, when the flag BLMEASOUT switches, a time T has elapsed such that:

$$V I R W R ( T ) = V D D \cdot ( 1 - exp ( - \frac{T}{R 3 \cdot n \cdot {C}_{BL}} ) ) = V D D \cdot \frac{R 2}{R 1 + R 2} \qquad$$

By measuring this time interval T, it is possible to calculate the mean capacitance value C_{BL} using the following equation:

$${C}_{BL} = \frac{T}{n \cdot {R}_{3} \cdot ln ( \frac{R 1 + R 2}{R 1} )} \qquad ( 3 )$$

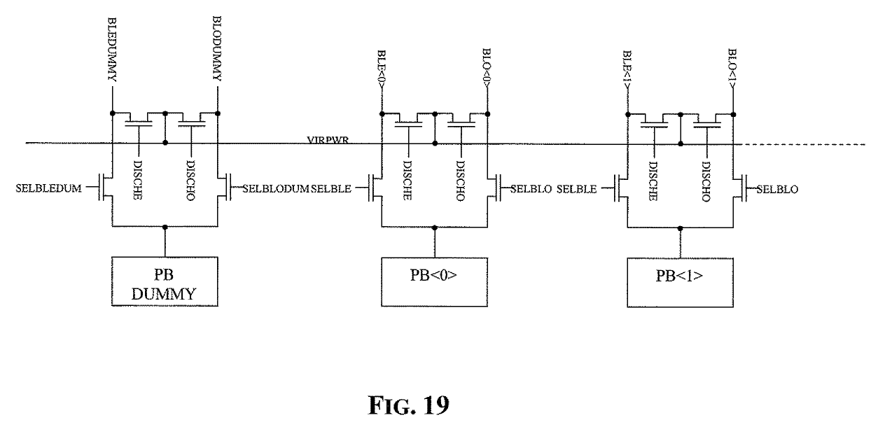

It is worth noticing that tolerances of fabrication of the resistor R3 may increase the uncertainty range of C_{BL}. For this reason, the circuit of FIG. 17 is preferred. The functioning is similar to that of the circuit of FIG. 14, but the common line VIRPWR is charged by a current generator I_{EXT} connected to it through a pad of the memory device. In this case, the voltage on the line VIRPWR increases (FIG. 18) according to the following equation:

$$V I R PWR ( t ) = \frac{{I}_{EXT} \cdot t}{n \cdot {C}_{BL}} \qquad ( 4 )$$

thus, the time T satisfies the following equation:

$$V I R PWR ( T ) = \frac{{I}_{EXT} \cdot T}{n \cdot {C}_{BL}} = V D D \cdot \frac{R 2}{R 1 + R 2}$$

and the mean capacitance value C_{BL} is:

$${C}_{BL} = \frac{{I}_{EXT} \cdot T}{n \cdot V D D \cdot \frac{R 2}{R 1 + R 2}} \qquad ( 5 )$$

Therefore, the value C_{BL} does not depend on the resistance R3.

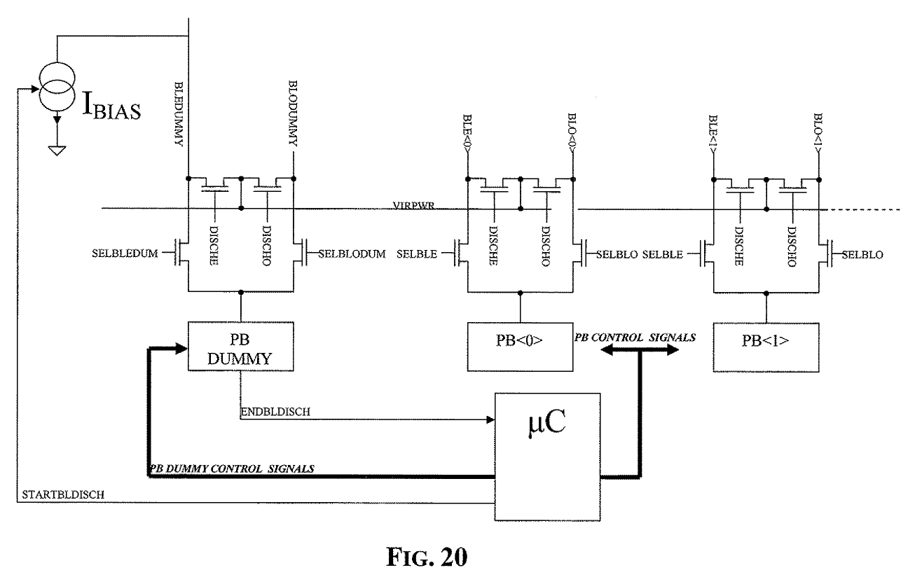

According to another embodiment, the evaluation time Teval may be fixed without measuring the mean capacitance of the bitlines. This may be done in a memory device of FIG. 19 that includes spare memory cells connected to dummy bitlines BLEDUMMY, BLODUMMY controlled by a properly designed page buffer PB DUMMY.

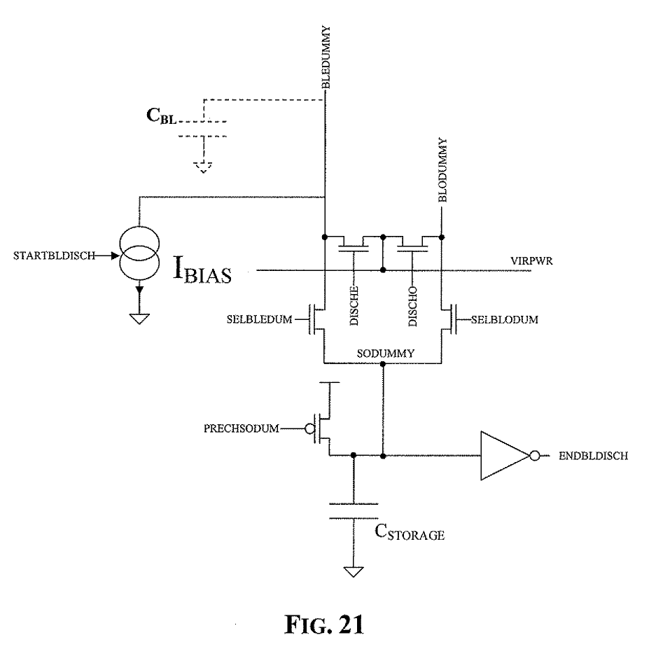

FIG. 20 depicts a more detailed view of the memory device of FIG. 19 that shows also how a microcontroller μC conditions all the page buffers of the memory device. According to another method for fixing the evaluation time Teval, it is assumed that the capacitance of the dummy bitline BLEDUMMY or BLODUMMY (or the mean capacitance of all the dummy bitlines of the memory device) be substantially equal to the mean capacitance of the bitlines addressable by a user. With this assumption, the evaluation time Teval is the time required by a dummy bitline BLEDUMMY (or BLODUMMY) to discharge from the charge read voltage V1 to the discrimination read voltage V2 when a current Icell is drawn therethrough.

In more detail, the signals SELBLE and SELBLEDUM are made equal to the voltage V1 so that the dummy bitline BLEDUMMY (or BLODUMMY) and the bitlines addressable by the user are biased approximately with the voltage V1. They are biased with the voltage V1-Vth, wherein Vth is the threshold voltage of the selection switch.

Then the signal SELBLE is grounded and SELBLEDUM is set to the discrimination voltage V2. At the same time, the microcontroller μC enables a start flag STARTBLDISCH and the current generator Icell starts discharging the dummy line BLEDUMMY.

When the voltage on the dummy bitline BLEDUMMY drops such to turn off the respective selection switch (i.e., the voltage on the bitline dummy is V2-Vth), the dummy page buffer PB DUMMY detects this event and switches the flag ENDBLDISCH. Therefore, the microcontroller μC fixes the time Teval as the time interval between an active edge of the start flag STARTBLDISCH and the subsequent edge of the flag ENDBLDISCH.

This method of fixing the evaluation time Teval is particularly convenient because it may be implemented at each power on of the memory device, or at the beginning of each erase or program phase or even before executing each read phase. Therefore, even if the capacitance of addressable bitlines of the memory device varies, because of fluctuations of temperature or of other functioning conditions, this technique may provide the value Teval for correctly discriminating the state of the memory cells.

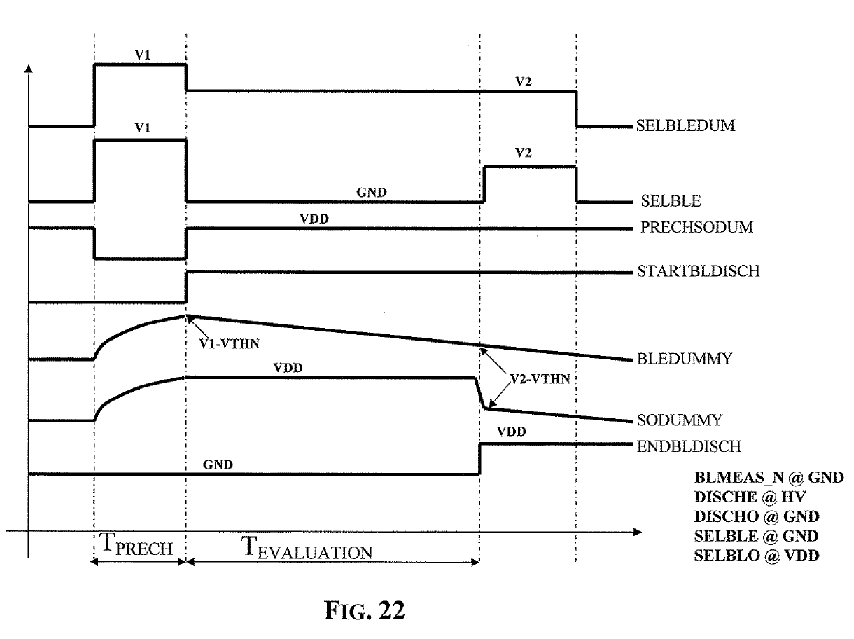

FIG. 21 is a detailed view of a sample embodiment of the dummy page buffer PB DUMMY of FIG. 20. FIG. 22 is a timing diagram of the signals of FIG. 21 that illustrates the above-described technique. It is possible to connect n dummy bitlines in parallel and determine the evaluation time Teval according to the previous technique by using a discharge current generator that draws a current n*Icell.

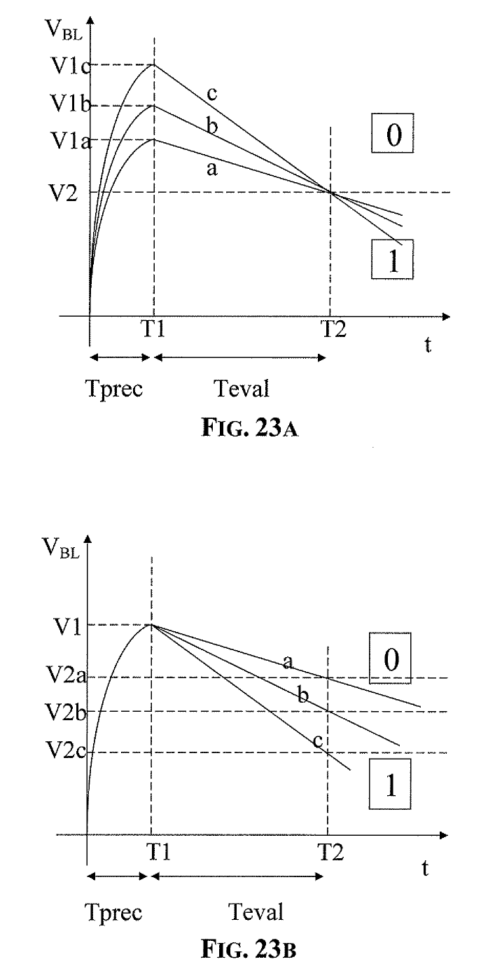

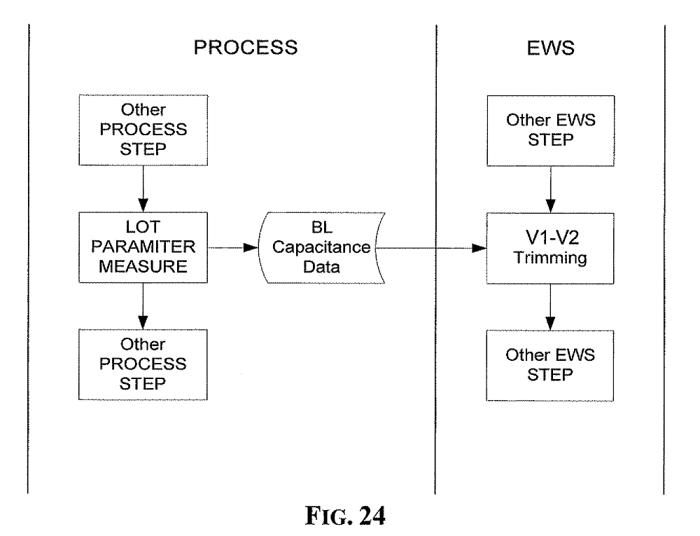

According to an alternative embodiment, instead of the evaluation time Teval, it is the voltage difference between the read charge voltage V1 and the read discriminating voltage V2 that is fixed preferably by trimming fuses during an EWS phase. FIGS. 23a and 23b illustrate how such a difference may be trimmed.

If the read discrimination voltage V2 is already established (FIG. 23a), the read charge voltage V1 is adjusted for each device: a, b, c by calculating the capacitance CBLa, CBLb, CBLc of each device a, b, c, respectively, and using the same equation (5) for estimating the respective charge voltage such that the voltage on the bitline VBL crosses the discrimination voltage V2 with a discharge time substantially equal to Teval.

Alternatively, the read charge voltage V1 and the evaluation time may be pre-established (FIG. 23b) and the read discrimination voltage V2 is adjusted for each device a, b, c such that the voltage on the bitline VBL crosses the discrimination voltage V2a, V2b, V2c, respectively, in a time substantially equal to Teval.

The voltage difference V1−V2 may be fixed with a fuse trimming operation carried out during an EWS test phase, as schematically depicted in FIG. 24. The voltage difference V1−V2 may also be fixed at each power on of the memory device, or at the beginning of each erase phase or even before executing each read phase. In this case, trimming parameters are permanently stored in a dedicated memory block.

The illustrated methods have been disclosed referring to cells that may assume either one of two logic states (0 and 1), but as will be immediately recognized by those skilled in the art, the same observations hold for a multilevel memory using cells that may assume one of three or more logic states. For example, in a two-bit-per-cell memory device, each cell may assume one of four different logic states, thus there are three read discrimination voltages and three evaluation times. The disclosed methods may be used also for fixing each evaluation time (or each difference between the read charge voltage and a read discriminating voltage) of each cell of such a multilevel memory device.

That which is claimed:

1. A method of fixing an evaluation time (Teval) of the programmed or erased state of a cell of an array of rows and columns of cells of a non-volatile NAND memory device, individually addressable through word lines and bitlines chargeable at certain read voltage levels, passed which from the instant the bitlines of said cell is charged at a read charge voltage (V1), a sense circuit assesses the state of the cell in order to produce at output of the memory device a certain read data, comprising the step of fixing said evaluation time (Teval) of each memory device in function of at least said read charge voltage (V1) of the bitline, of a read discriminating voltage (V2) and of a certain discharge current through the cells (Icell) once for all during a test-on-wafer phase (EWS) of the device or repeatedly during operation of the finished memory device.

2. The method of claim 1, characterized by comprising the steps of
establishing an average value of capacitance (C_{BL}) of a single bitline of the memory array by measuring the capacitance of a predefined plurality of bitlines of the memory array;
fixing said evaluation time (Teval) of each memory device in function of said average capacitance value (C_{BL}) of a bitline.

3. The method according to claim 1, wherein said evaluation time (Teval) is fixed at a phase of operation of the memory device chosen from the power-on phase and at start of an erase or program or read operation.

4. The method according to claim 2, including the steps of:
measuring the total capacitance of even or odd bitlines of the memory array;
establishing said average value of bitline capacitance (C_{BL}) by dividing the measured capacitance by the number of either even or odd bitlines charged to said read charge voltage (V1) in parallel.

5. The method of claim 4, comprising the steps of:
biasing either all even or all odd bitlines of the memory array by connecting them in parallel to a common ground line;
charging in parallel said bitlines by connecting said common line to a power supply rail of the memory device through an auxiliary resistance (R3);
comparing the voltage on said common line with a reference voltage V_{REF};
measuring the charging time (T) of said bitlines for reaching on said common line a voltage equal to said reference voltage (V_{REF});
calculating the total capacitance of said bitlines in function of said time of charging (T) of said auxiliary resistance (R3) and of said reference voltage (V_{REF}).

6. The method of claim 4, comprising the steps of
biasing either all even or all odd bitlines of the memory array by connecting them in parallel to a common ground line;
charging in parallel said bitlines by connecting said common line to a constant current generator of a certain current (I_{EXT});
comparing the voltage on said common line with a reference voltage V_{REF};
measuring the charging time (T) of said bitlines for reaching on said common line a voltage equal to said reference voltage (V_{REF});
calculating the total capacitance of said bitlines in function of said time of charging (T) of said auxiliary resistance (R3) and of said reference voltage (V_{REF}).

7. The method of claim 3, wherein said memory device comprises additional dummy bitlines memory cells, the method comprising the steps of biasing at least one of said dummy bitlines at said red charging voltage (V1);
discharging said dummy bitlines at said certain pre-established discharge current (Icell);
fixing said evaluation time (Teval) by measuring the time needed for discharging said dummy bitline from said read charging voltage (V1) to said read discrimination voltage level (V2).

8. A method of fixing the difference between a read charge voltage (V1) and a read discriminating voltage (V2) of the programmed or erased state of a cell of an array of rows and columns of cells of a non-volatile NAND memory device, individually addressable through word lines and bitlines chargeable at certain read voltage levels, the memory device including a sense circuit suitable to assess the state of the cell in order to produce at output of the memory device a certain read data when an evaluation time (Teval) is passed from the instant the bitline of said cell is charged at the read charge voltage (V1), the method comprising the step of fixing said evaluation time (Teval) of each memory device,
characterized in that it comprises the step of fixing said voltage difference (V1−V2) between the read charge voltage (V1) and the read discriminating voltage (V2) in function of said evaluation time (Teval) and of a certain discharge current through the cells (Icell) once for all during a test-on-wafer phase (EWS) of the device or repeatedly during operation of the finished memory device.

9. The method of claim 8, characterized by comprising the steps of
establishing an average value of capacitance (C_{BL}) of a single bitline of the memory array by measuring the capacitance of a predefined plurality of bitlines of the memory array;
fixing said voltage difference (V1−V2) of each memory device in function of said average capacitance value (C_{BL}) of a bitline.

10. The method according to claim 8, wherein said voltage difference (V1−V2) is fixed at a phase of operation of the memory device chosen from the power-on phase and at start of an erase or program or read operation.

11. The method according to claim 9, including the steps of:
measuring the total capacitance of even or odd bitlines of the memory array;
establishing said average value of bitline capacitance (C_{BL}) by dividing the measured capacitance by the number of either even or odd bitlines charged to said read charge voltage (V1) in parallel.

12. The method of claim 11, comprising the steps of:
biasing either all even or all odd bitlines of the memory array by connecting them in parallel to a common ground line;
charging in parallel said bitlines by connecting said common line to a power supply rail of the memory device through an auxiliary resistance (R3);
comparing the voltage on said common line with a reference voltage V_{REF};
measuring the charging time (T) of said bitlines for reaching on said common line a voltage equal to said reference voltage (V_{REF});
calculating the total capacitance of said bitlines in function of said time of charging (T) of said auxiliary resistance (R3) and of said reference voltage (V_{REF}).

13. The method of claim 11, comprising the steps of
biasing either all even or all odd bitlines of the memory array by connecting them in parallel to a common ground line;
charging in parallel said bitlines by connecting said common line to a constant current generator of a certain current (I_{EXT});
comparing the voltage on said common line with a reference voltage V_{REF};
measuring the charging time (T) of said bitlines for reaching on said common line a voltage equal to said reference voltage (V_{REF});
calculating the total capacitance of said bitlines in function of said time of charging (T) of said auxiliary resistance (R3) and of said reference voltage (V_{REF}).

14. A non-volatile NAND type memory device including a circuit for fixing an evaluation time (Teval) of the programmed or erased state of a cell of an array of rows and columns of cells of a non-volatile NAND memory device, individually addressable through word lines and bitlines chargeable at certain read voltage levels, passed which from the instant the bitlines of said cell is charged at a read charge voltage (V1), a sense circuit assesses the state of the cell in order to produce at output of the memory device a certain read data, comprising the step of:
said circuit for fixing the evaluation time (Teval) comprising:
a voltage divider (R1, R2) referred to ground and connected to a power supply line of the memory device through a switch controlled by a control signal (BLMEANS_N), generating a reference voltage (V_{REF});
a comparator for comparing the voltage on a common line of said bitlines of the memory array with said reference voltage (V_{REF}), generating a flag (BLMEASOUT) active when said reference voltage (V_{REF}) is surpassed;
circuit means for charging said common line of said bitlines.

15. The device of claim 14, wherein said circuit means comprise an auxiliary resistance (R3) connected to said power supply line through a second switch controlled by said control signal (BLMEAS_N).

16. The device of claim 14, wherein said circuit means comprise a current generator (I_{EXT}) connected to said power supply voltage line through a pad of the memory device.

17. A non-volatile NAND type memory device including a circuit for fixing an evaluation time (Teval) of the programmed or erased state of a cell of an array of rows and columns of cells of a non-volatile NAND memory device, individually addressable through word lines and bitlines chargeable at certain read voltage levels, passed which from the instant the bitlines of said cell is charged at a read charge voltage (V1), a sense circuit assesses the state of the cell in order to produce at output of the memory device a certain read data, comprising:
at least a dummy bitline;
means for loading said dummy bitline at said read charging voltage (V1);
a constant current generator (Ibias) for discharging said dummy bitline when enabled by a control signal (STARTBLDISCH);
a flag generating circuit (ENDBLDISCH) active when said dummy bitline reaches a pre-established read discrimination voltage level (V2);
a microprocessor receiving said flag (ENDBLDISCH), for generating said control signal (STARTBLDISCH) and fixing the evaluation time (Teval) according to the method of claim 7.

18. A method of testing-on-wafer (EWS) a non-volatile NAND type memory device having a circuit for fixing an evaluation time (Teval) of the programmed or erased state of a cell of an array of rows and columns of cells of a non-volatile NAND memory device, individually addressable through word lines and bitlines chargeable at certain read voltage levels, passed which from the instant the bitlines of said cell is charged at a read charge voltage (V1), a sense circuit assesses the state of the cell in order to produce at output of the memory device a certain read data, comprising the following steps:
establishing an average value of capacitance (C_{BL}) of a single bitline of the memory array by measuring the capacitance of a pre-defined plurality of bitlines of said array;
fixing said evaluation time (Teval) of each memory device in function of at least said read charging voltage (V1) of the bitlines, of a read discrimination voltage level (V2), of a certain discharge current through said cell (Icell) and of said average capacitance value (C_{BL}) through the setting of trimming means of the memory device.

19. A method of testing-on-wafer (EWS) a non-volatile NAND type memory device having a circuit for fixing an evaluation time (Teval) of the programmed or erased state of a cell of an array of rows and columns of cells of a non-volatile NAND memory device, individually addressable through word lines and bitlines chargeable at certain read voltage levels, passed which from the instant the bitlines of said cell is charged at a read charge voltage (V1), a sense circuit assesses the state of the cell in order to produce at output of the memory device a certain read data, comprising the following steps:
establishing an average value of capacitance (C_{BL}) of a single bitline of the memory array by measuring the capacitance of a pre-defined plurality of bitlines of said array;
fixing the difference between said read charging voltage (V1) of the bitlines and a read discrimination voltage level (V2), in function of at least said evaluation time (Teval), of a certain discharge current through said cell (Icell) and of said average capacitance value (C_{BL}) through the setting of trimming means of the memory device.
